(19) United States
(12) Patent Application Publication
(10) Pub. No.: US 2024/0008237 A1
(43) Pub. Date: Jan. 4, 2024

(54) COMPONENT-MOUNTING MACHINE AND COMPONENT-MOUNTING METHOD

(71) Applicant: FUJI CORPORATION, Chiryu (JP)

(72) Inventor: Takeshi SAKURAYAMA, Nisshin-shi (JP)

(73) Assignee: FUJI CORPORATION, Chiryu (JP)

(21) Appl. No.: 18/252,387

(22) PCT Filed: Dec. 14, 2020
(86) PCT No.: PCT/JP2020/046496

§ 371 Date: May 10, 2023

(51) Int. Cl. H05K 13/04; H05K 13/08

(52) U.S. Cl. CPC H05K 13/0409; H05K 13/081

(57) ABSTRACT

A component mounting machine includes a suction tool configured to pick up the component at a pickup height distant from a reference height by a distance indicated by an offset amount; a moving mechanism configured to move the suction tool to the pickup height; an attempt section configured to perform an attachment operation a predetermined count number; a first calculation section configured to calculate a suction rate indicating a ratio of successfully picking up the component by the suction tool during the attachment operation of the predetermined count number; and an updating section configured to update the offset amount within a predetermined range by adding or subtracting a predetermined distance to or from the offset amount when the suction rate is less than a determination value, and further repeat the attempt section and the first calculation section.

### TECHNICAL FIELD

The present disclosure relates to a component mounting machine for executing an attachment operation for attaching a component to a board.

### BACKGROUND ART

Conventionally, various technologies have been proposed for the component mounting machine described above. For example, the technology described in Patent Literature 1 discloses an electronic component mounting device which performs mounting by holding or attaching an electronic component by a holding means using a mounting condition including a condition in a height direction orthogonal to an XY-plane, the electronic component mounting device includes means for specifying positional information of the held electronic component on the XY-plane and positional information of the attached electronic component on the XY-plane by using a predetermined mounting condition; means for specifying a variation in a position of the held electronic component on the XY-plane and a variation in a position of the attached electronic component on the XY-plane by using the positional information of the specified electronic component on the XY-plane; means for specifying multiple variations in positions of the electronic components on the XY-plane by changing the predetermined mounting condition multiple times; and means for specifying a mounting condition of the electronic component by using multiple variations specified in positions of the electronic components on the XY-plane.

Further, the means for specifying the mounting condition of the electronic component specifies, as the mounting condition, a stop position of the holding means in the height direction when holding the electronic component and a stop position of the holding means in the height direction when attaching the electronic component, using the multiple variations specified in the positions of the electronic component on the XY-plane.

As a result, the technology described in Patent Literature 1 can improve the accuracy of the mounting operation relating to the holding or attachment of the electronic component by the electronic component mounting device.

### PATENT LITERATURE

Patent Literature 1: Japanese Patent Publication No. 6076047

### BRIEF SUMMARY

### Technical Problem

However, even if the stop position of the holding means in the height direction in holding the electronic component is specified in this manner, a statistical probability that an event in which the holding of the electronic component failed occurs may be relatively high, and in such a case, it is necessary to finely adjust the stop position after the specification.

The present disclosure has been made in view of the points which are described above and an object of the present disclosure is to provide a component mounting machine capable of finding a pickup height suitable for an attachment operation and performing the attachment operation at the found pickup height during repeating the attachment operation of attaching a component picked up by a suction tool to a board at the pickup height.

### Solution to Problem

The present specification discloses a component mounting machine for executing an attachment operation for attaching a component to a board, the component mounting machine including: a suction tool configured to pick up the component at a pickup height distant from a reference height by a distance indicated by an offset amount; a moving mechanism configured to move the suction tool to the pickup height; an attempt section configured to perform the attachment operation a predetermined count number; a first calculation section configured to calculate a suction rate indicating a ratio of successfully picking up the component by the suction tool during the attachment operation of the predetermined count number; and an updating section configured to update the offset amount within a predetermined range by adding or subtracting a predetermined distance to or from the offset amount when the suction rate is less than a determination value, and further repeat the attempt section and the first calculation section.

### Advantageous Effects

According to the present disclosure, the component mounting machine can find the pickup height suitable for the attachment operation and perform the attachment operation at the found pickup height, during repeating the attachment operation for attaching the component picked up by the suction tool to the board at the pickup height.

### BRIEF DESCRIPTION OF DRAWINGS

FIG. 1 is a perspective view illustrating a mounting machine of the present embodiment.

FIG. 2 is a diagram illustrating a control configuration of the mounting machine.

FIG. 3 is a diagram illustrating an example of a change of a pickup height in an attachment operation of the mounting machine.

FIG. 4 is a diagram illustrating an example of a change of a pickup height in an attachment operation of the mounting machine.

FIG. 5 is a diagram illustrating an example of a change of a pickup height in an attachment operation of the mounting machine.

FIG. 6 is a diagram illustrating an example of a change of a pickup height in an attachment operation of the mounting machine.

FIG. 7 is a diagram illustrating an example of a change of a pickup height in an attachment operation of the mounting machine.

FIG. 8 is a diagram illustrating an example of stored contents of a data table provided in an EEPROM of the mounting machine.

FIG. 9 is a diagram illustrating an example of an image captured by a parts camera of the mounting machine.

FIG. 10 is a diagram illustrating an example of a change of a pickup height in an attachment operation of the mounting machine.

FIG. 11 is a diagram illustrating an example of a change of a pickup height in an attachment operation of the mounting machine.

FIG. 12 is a diagram illustrating an example of a change of a pickup height in an attachment operation of the mounting machine.

FIG. 13 is a diagram illustrating an example of a change of a pickup height in an attachment operation of the mounting machine.

FIG. 14 is a diagram illustrating an example of a change of a pickup height in an attachment operation of the mounting machine.

FIG. 15 is a diagram illustrating an example of a change of a pickup height in an attachment operation of the mounting machine.

FIG. 16 is a flowchart illustrating a control program of a first component mounting method.

FIG. 17 is a flowchart illustrating the control program of the first component mounting method.

FIG. 18 is a flowchart illustrating a control program of a second component mounting method.

FIG. 19 is a flowchart illustrating the control program of the second component mounting method.

FIG. 20 is a flowchart illustrating a control program of a third component mounting method.

FIG. 21 is a flowchart illustrating the control program of the third component mounting method.

FIG. 22 is a flowchart illustrating the control program of the third component mounting method.

### DESCRIPTION OF EMBODIMENTS

Hereinafter, preferred embodiments of the present disclosure will be described in detail with reference to the drawings. However, in the drawings, a portion of the configuration is omitted, and the dimensional ratio or the like of each illustrated portion is not always accurate. In the drawings, reference sign D1 represents an X-axis direction that is a left-right direction. Reference sign D2 represents a Y-axis direction that is a front-rear direction. Reference sign D3 represents a Z-axis direction that is an up-down direction.

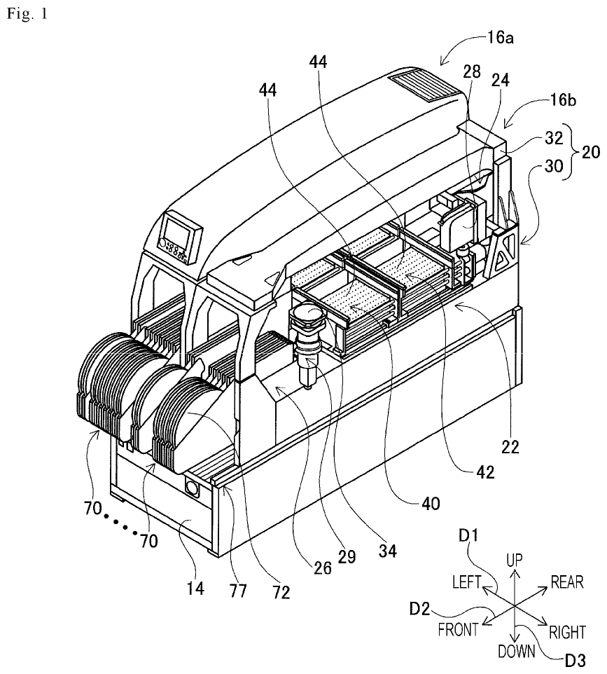

As illustrated in FIG. 1, in the present embodiment, two mounting machines 16a and 16b are installed on common base 14 in an adjacently arranged state. X-axis direction D1 is a horizontal direction in which respective mounting machines 16a and 16b are arranged adjacent to each other. Y-axis direction D2 is a horizontal direction orthogonal to X-axis direction D1. Z-axis direction D3 is a direction orthogonal to both X-axis direction D1 and Y-axis direction D2, that is, the horizontal plane. Accordingly, X-axis direction D1, Y-axis direction D2, and Z-axis direction D3 are orthogonal to each other.

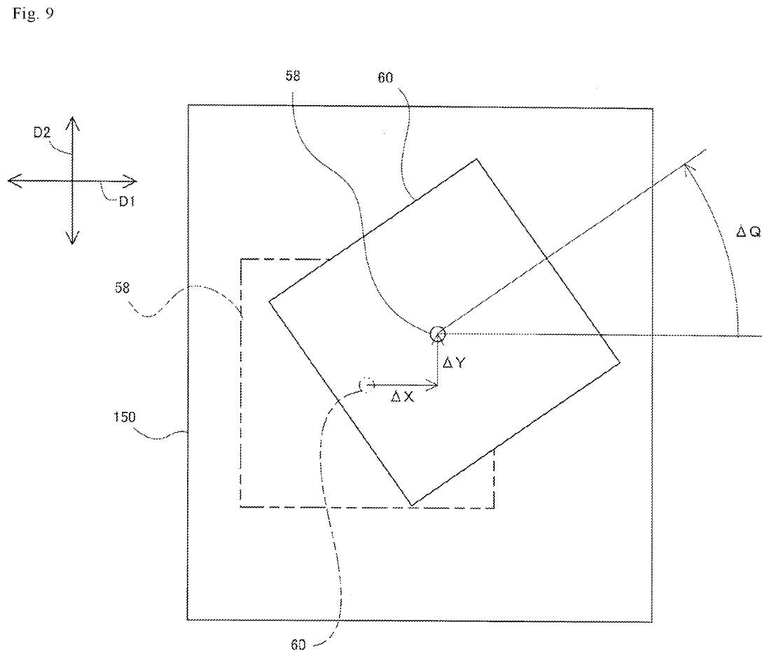

Each of mounting machines 16a and 16b has the same configuration. Hereinafter, in a case where each of mounting machines 16a and 16b is collectively referred to without being distinguished from each other, it will be referred to as mounting machine 16. Mounting machine 16 includes mounting machine main body 20, conveyance device 22, moving device 24, supply device 26, mounting head 28, imaging device 29, and the like. Mounting machine 16 performs an attachment operation for attaching electronic component 58 (see FIG. 9) to circuit board 44, such as a printed circuit board, conveyed by conveyance device 22.

Mounting machine main body 20 has frame section 30 and beam section 32. Beam section 32 is bridged above frame section 30. Tape feeder support table 77 is provided at an end portion on the front side of frame section 30.

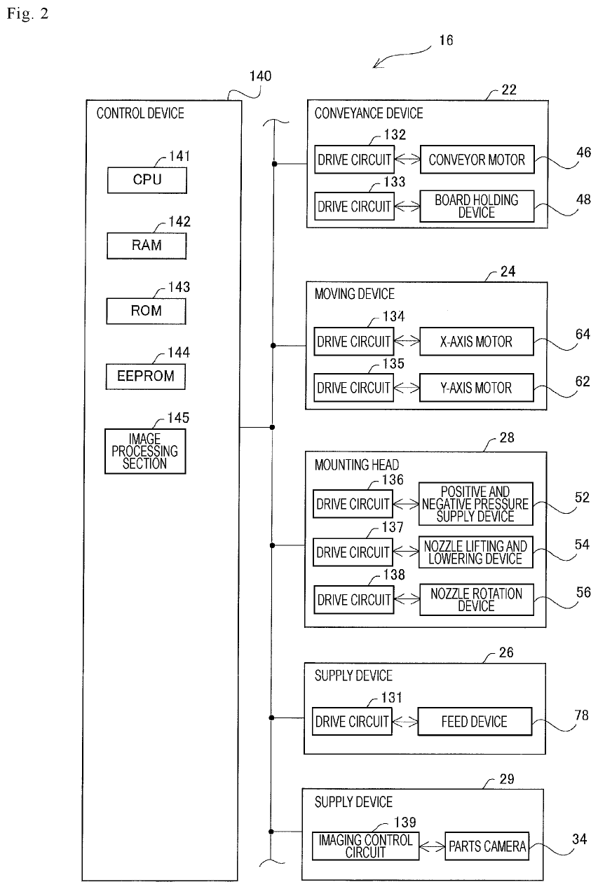

Conveyance device 22 includes two conveyor devices 40 and 42 and board holding device 48 (see FIG. 2). Each of conveyor devices 40 and 42 extends in X-axis direction D1 and is provided in frame section 30 in parallel with each other. Each of conveyor devices 40 and 42 conveys circuit board 44 supported by each of conveyor devices 40 and 42 in X-axis direction D1 by using conveyor motor 46 (see FIG. 2) as a drive section or the like. Board holding device 48 pushes up and fixes conveyed circuit board 44 at a predetermined position.

Moving device 24 includes a Y-axis direction slide mechanism, an X-axis direction slide mechanism, and the like (not illustrated). The Y-axis direction slide mechanism includes a pair of guide rails extending in Y-axis direction D2, a slider, Y-axis motor 62 (see FIG. 2), and the like (not illustrated). The guide rail is fixed to beam section 32. The slider is guided by the guide rail in response to the driving of Y-axis motor 62 and moves to any position in Y-axis direction D2. Similarly, the X-axis direction slide mechanism includes a pair of guide rails extending in X-axis direction D1, a slider, X-axis motor 64 (FIG. 2), and the like (not illustrated). The guide rail of the X-axis direction slide mechanism is fixed to the slider of the Y-axis direction slide mechanism. The slider of the X-axis direction slide mechanism is guided by the guide rail of the X-axis direction slide mechanism in response to the driving of X-axis motor 64, and moves to any position in X-axis direction D1. Mounting head 28 is fixed to the slider of the X-axis direction slide mechanism. Mounting head 28 picks up electronic component 58 and attaches the same to circuit board 44.

Supply device 26 is a feeder-type supply device and is provided at an end portion on the front side of frame section 30. Supply device 26 includes multiple tape feeders 70. Tape feeder 70 is supported by tape feeder support table 77. Tape feeder 70 feeds and supplies electronic component 58 to a downstream side of tape feeder 70 by drawing and unsealing the taped component wound on reel 72 in response to the driving of feed device 78 (see FIG. 2).

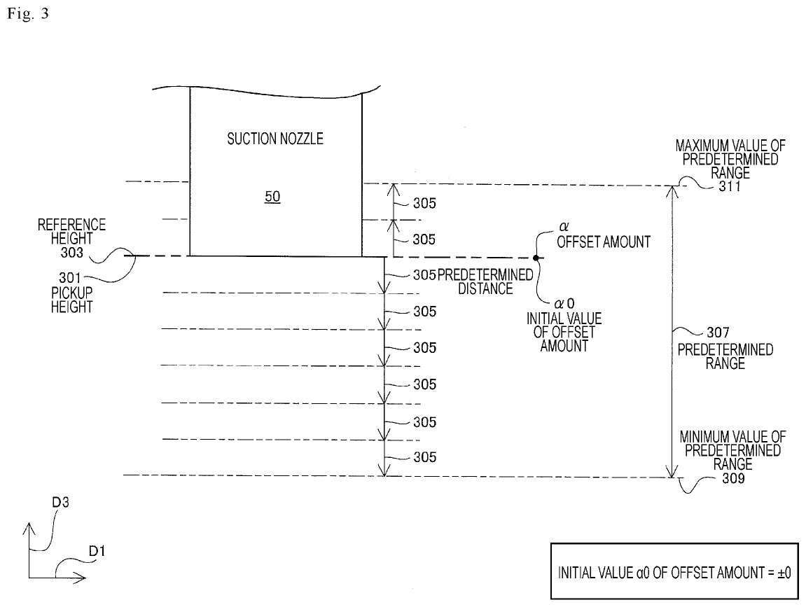

Mounting head 28 includes four suction nozzle shafts (not illustrated), positive and negative pressure supply device 52 (FIG. 2), nozzle lifting and lowering device 54 (FIG. 2), nozzle rotation device 56 (FIG. 2), and the like. Each suction nozzle shaft is uniformly disposed in the XY-plane (horizontal plane) with respect to the axis of mounting head 28 having a substantially circular shape in the XY-plane (horizontal plane). A suction nozzle holder (not illustrated) is fixed below the suction nozzle shaft. The suction nozzle holder detachably holds suction nozzle 50 (see FIG. 3 and the like). In addition, a supply passage through which the negative pressure air and the positive pressure air are supplied from positive and negative pressure supply device 52 is formed in mounting head 28. As a result, mounting head 28 picks up electronic component 58 at the lower end face of suction nozzle 50 by the supply of the negative pressure air, and can release picked-up electronic component 58 by the supply of slight positive pressure air.

Nozzle lifting and lowering device 54 lifts and lowers the suction nozzle shaft in the up-down direction, that is, in Z-axis direction D3. Nozzle rotation device 56 revolves the suction nozzle shaft around the axial center of mounting head 28. Specifically, nozzle rotation device 56 intermittently rotates the suction nozzle shaft at every predetermined stop position. In addition, the nozzle lifting and lowering device lifts and lowers the suction nozzle shaft at a predetermined lifting and lowering position, which is one of the four stopping positions. Nozzle rotation device 56 rotates the suction nozzle shaft about the axial center thereof. As a result, mounting head 28 can change the position of electronic component 58 picked up by suction nozzle 50 in the up-down direction, and the orientation of electronic component 58 in the horizontal plane view.

Imaging device 29 includes parts camera 34 and the like. Parts camera 34 is disposed in frame section 30 in a state of being directed upward between conveyance device 22 and supply device 26.

Next, an attachment operation of mounting machine 16 will be described. Circuit board 44 is conveyed to a predetermined position by conveyor devices 40 and 42, and is fixed by board holding device 48. Meanwhile, moving device 24 moves mounting head 28 to supply device 26. Next, mounting head 28 causes suction nozzle 50 to be in a state where suction nozzle 50 is lowered above the supply position of supply device 26 until the lower end face thereof reaches pickup height 301 (see FIG. 3 and the like), so that electronic component 58 is picked up by suction nozzle 50. Thereafter, suction nozzle 50 lifts. In addition, since mounting head 28 has four suction nozzle shafts, that is, four suction nozzles 50, it is possible to pick up maximum four electronic components 58. When mounting head 28 picks up multiple electronic components 58, the rotation of the suction nozzle shaft (that is, suction nozzle 50) by nozzle rotation device 56 to the lifting and lowering position, and the lifting and lowering of the suction nozzle shaft (that is, suction nozzle 50) at the lifting and lowering position by nozzle lifting and lowering device 54 are repeated.

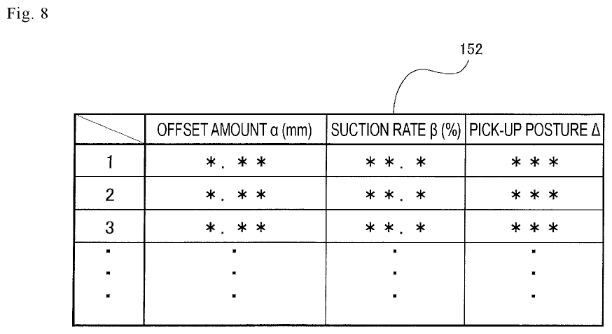

Subsequently, moving device 24 moves mounting head 28 that has picked up electronic component 58 with suction nozzle 50 to a position above parts camera 34. Next, image 150 (see FIG. 9) of electronic component 58 in a state of being picked up by suction nozzle 50 is captured by parts camera 34, and image data is obtained. Based on the image data, data as to pick-up posture Δ (see FIG. 8) of electronic component 58, which will be described later, or the like is obtained.

Next, moving device 24 moves mounting head 28 to a position above the attachment position of circuit board 44. Next, mounting head 28 lowers suction nozzle 50 to a position in the vicinity of circuit board 44, and electronic component 58 is released from suction nozzle 50. When mounting head 28 attaches multiple electronic components 58 in the same manner as in the case of the pickup of electronic components 58, the rotation of the suction nozzle shaft (that is, suction nozzle 50) by nozzle rotation device 56 to the lifting and lowering position, and the lifting and lowering of the suction nozzle shaft (that is, suction nozzle 50) at the lifting and lowering position by nozzle lifting and lowering device 54 are repeated. Further, by repeating a series of attachment operations from the pickup to the release of electronic component 58 by mounting head 28, multiple electronic components 58 are attached to circuit board 44.

A control system configuration of mounting machine 16 will be described with reference to FIG. 2. In addition to the above-described configuration, mounting machine 16 includes control device 140 and the like. Control device 140 includes CPU 141, RAM 142, ROM 143, and the like. CPU 141 controls respective sections electrically connected by executing various programs stored in ROM 143. Here, the respective sections include conveyance device 22, moving device 24, mounting head 28, supply device 26, imaging device 29, and the like. RAM 142 is used as a main storage device for CPU 141 to execute various types of processing. ROM 143 stores a control program, various data, and the like.

In addition to the above-described configuration, conveyance device 22 includes drive circuit 132 for driving conveyor motor 46, drive circuit 133 for driving board holding device 48, and the like. In addition to the above-described configuration, moving device 24 includes drive circuit 134 for driving X-axis motor 64, drive circuit 135 for driving Y-axis motor 62, and the like.

In addition to the above-described configuration, mounting head 28 includes drive circuit 136 for driving positive and negative pressure supply device 52, drive circuit 137 for driving nozzle lifting and lowering device 54, drive circuit 138 for driving nozzle rotation device 56, and the like. In addition to the above-described configuration, supply device 26 includes drive circuit 131 for driving feed device 78 and the like.

In addition to the above-described configuration, imaging device 29 includes imaging control circuit 139 for controlling parts camera 34 and the like.

In addition to the above-described configuration, control device 140 includes EEPROM 144, image processing section 145 and the like. EEPROM 144 stores various data necessary for executing the attachment operation. Control device 140 acquires data necessary for the attachment operation from EEPROM 144 in addition to ROM 143 described above. Image processing section 145 can perform image processing according to a well-known technology. Image processing section 145 processes, for example, image data of image 150 captured by parts camera 34, and causes control device 140 to acquire data such as pick-up posture Δ of electronic component 58.

Next, referring to FIGS. 3 to 7, pickup height 301 and the change of pickup height 301 in the attachment operation of mounting machine 16 will be described. Pickup height 301 means a position in the up-down direction occupied by the lower end face of suction nozzle 50 (that is, the position in Z-axis direction D3) when electronic component 58 at the supply position of supply device 26 is started to be picked up in a state where suction nozzle 50 is stopped. In mounting machine 16, pickup height 301 is changed to a height suitable for the repeated attachment operation during repeating the attachment operation.

Therefore, pickup height 301 is set at a position distant from reference height 303 by a distance indicated by offset amount α in the up-down direction (that is, Z-axis direction D3). Reference height 303 is set, for example, to a position in the up-down direction (that is, the position in Z-axis direction D3) occupied by a portion picked up by suction nozzle 50 among one or multiple upper faces of electronic component 58 at the supply position of supply device 26. Offset amount α is a variable that changes between minimum value 309 and maximum value 311 of predetermined range 307 by subtracting or adding predetermined distance 305 to initial value α0. In the examples illustrated in FIGS. 3 to 7, initial value α0 of offset amount α is ±0.

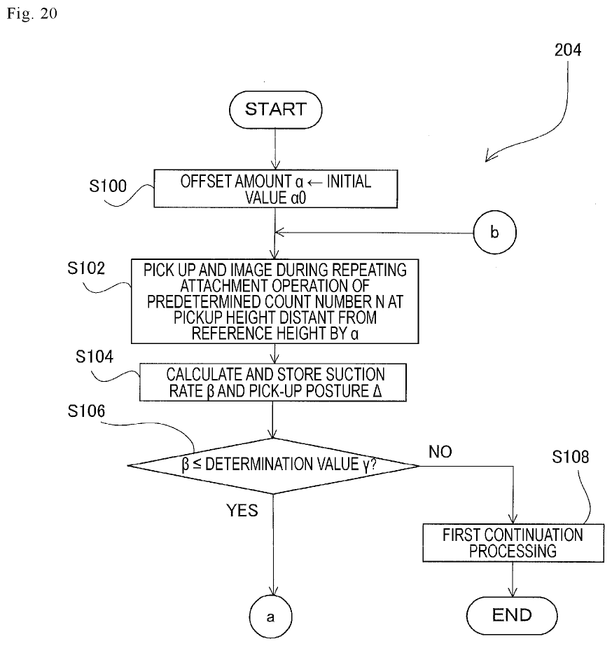

First, as illustrated in FIG. 3, the attachment operation of predetermined count number N (see FIG. 20) is repeated at pickup height 301 in a case where initial value α0 is substituted for offset amount α. Therefore, the attachment operation of predetermined count number N is repeated at pickup height 301 equal to reference height 303. At this time, suction rate β (see FIG. 8) is calculated. suction rate β means a statistical probability (ratio) that an event in which the pickup of electronic component 58 is successful by suction nozzle 50 occurs, during repeating the attachment operation of predetermined count number N.

The determination as to whether suction nozzle 50 succeeds in pickup of electronic component 58 or fails is made, for example, by image processing section 145 performing image processing on the image data of image 150 captured by parts camera 34. In this case, it is determined whether suction nozzle 50 succeeded in the pickup of electronic component 58 or failed in accordance with the position or the orientation of electronic component 58 in image 150. However, when image 150 in which only suction nozzle 50 is projected is captured, it is determined that suction nozzle 50 has failed to pick up electronic component 58.

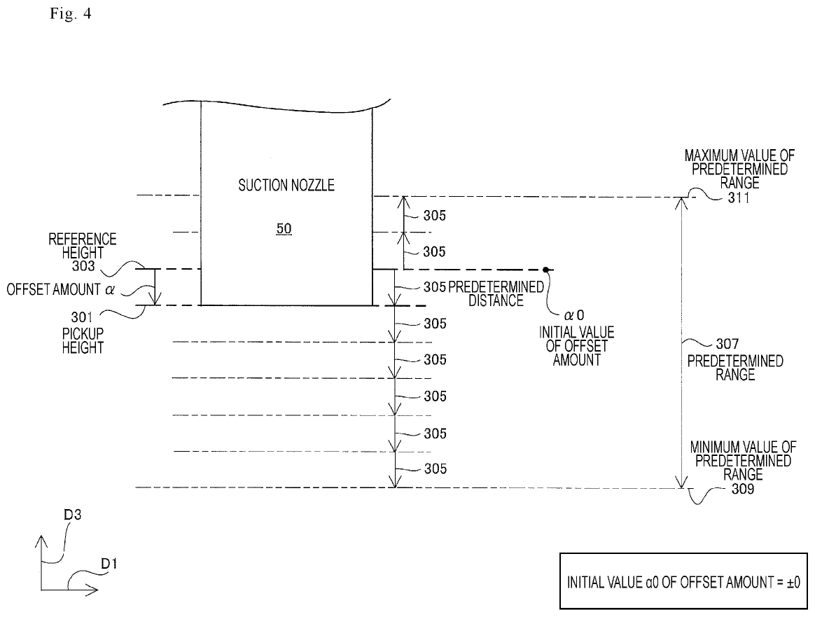

In a case where suction rate β is larger than determination value γ (see FIG. 20), pickup height 301 is fixed to the current height, that is, reference height 303, and the subsequent attachment operations are repeated. On the other hand, in a case where suction rate β is determination value γ or less, offset amount α is updated by subtracting predetermined distance 305 from offset amount α. Thereafter, as illustrated in FIG. 4, the attachment operation of predetermined count number N is repeated at pickup height 301 in a case where offset a is updated.

In a case where suction rate β is larger than determination value γ, pickup height 301 is fixed to the current height, that is, a height distant from reference height 303 by the distance indicated by offset amount α, and the subsequent attachment operations are repeated. On the other hand, in a case where suction rate β is determination value γ or less, offset amount α is updated by further subtracting predetermined distance 305 from offset amount α. Thereafter, the attachment operation of predetermined count number N is repeated at pickup height 301 in a case where offset a is updated.

Thereafter, in the same manner, repetition of update of offset amount α by the subtraction of predetermined distance 305 and the attachment operation of predetermined count number N is performed until suction rate β is larger than determination value γ and pickup height 301 is fixed to the current height.

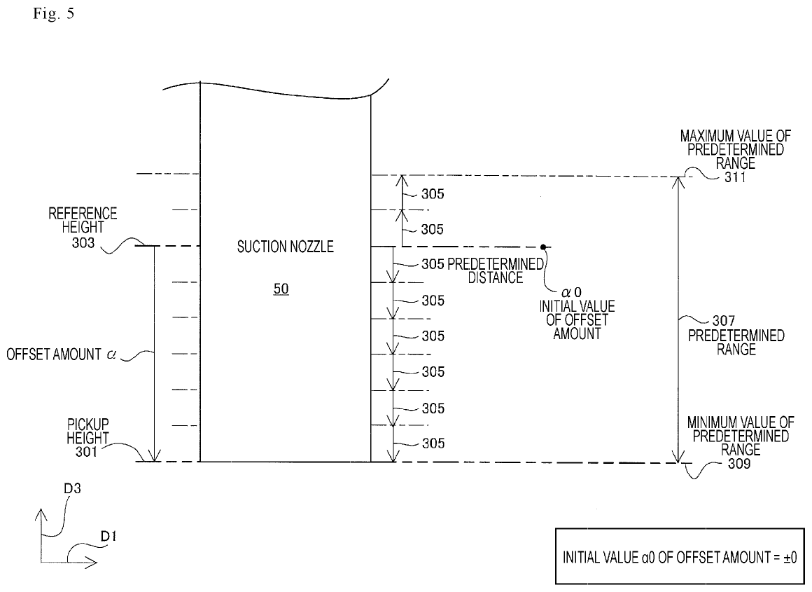

However, as illustrated in FIG. 5, in a case where offset amount α is equal to minimum value 309 of predetermined range 307, when suction rate β is not larger than determination value γ, the update of offset amount α is performed as follows. In the case of the examples illustrated in FIGS. 3 to 7, offset amount α is equal to minimum value 309 of predetermined range 307 when the update by the subtraction of predetermined distance 305 is performed six times.

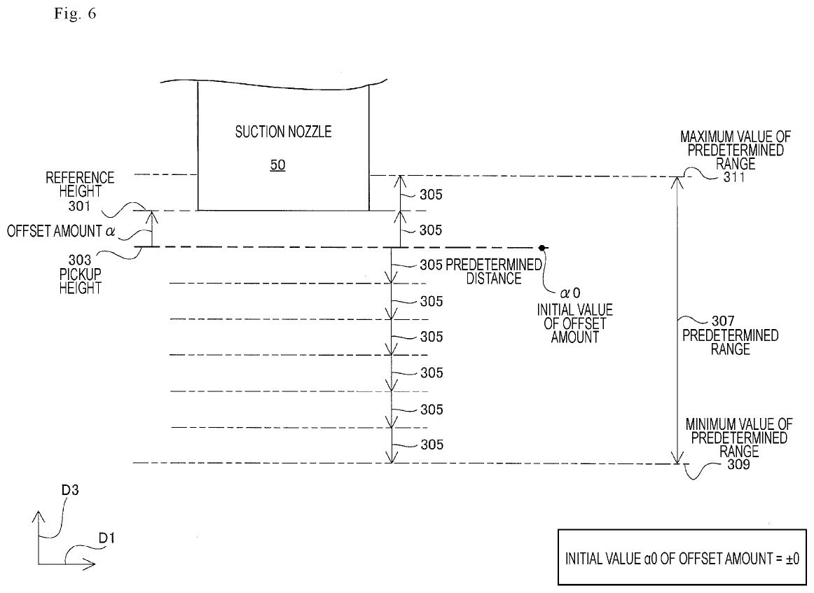

As illustrated in FIG. 6, a sum of initial value α0 and predetermined distance 305 is substituted for offset amount α. As a result, offset amount α is updated. Thereafter, the attachment operation of predetermined count number N is repeated at pickup height 301 in a case where offset amount α is updated.

In a case where suction rate β is larger than determination value γ, pickup height 301 is fixed to the current height, that is, a height distant from reference height 303 by the distance indicated by offset amount α, and the subsequent attachment operations are repeated. On the other hand, in a case where suction rate α is determination value γ or less, offset amount α is updated by adding predetermined distance 305 to offset amount α. Thereafter, the attachment operation of predetermined count number N is repeated at pickup height 301 in a case where offset amount α is updated.

Thereafter, in the same manner, the repetition of the update of offset amount α by the addition of predetermined distance 305 and the attachment operation of predetermined count number N is performed until suction rate β is larger than determination value γ and pickup height 301 is fixed to the current height.

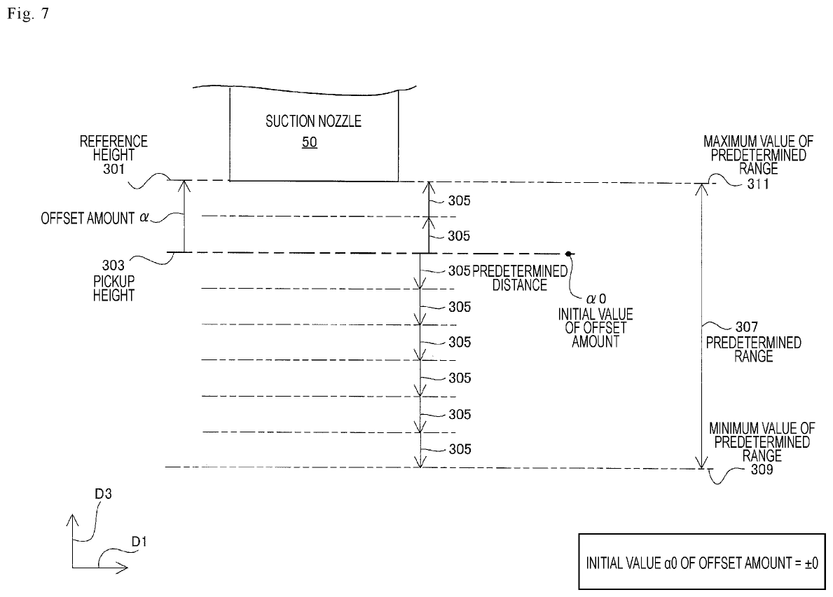

However, as illustrated in FIG. 7, in a case where offset amount α is equal to maximum value 311 of predetermined range 307, when suction rate β is not larger than determination value γ, the update of offset amount α is stopped, and after pickup height 301 is changed in the following manner, the subsequent attachment operations are repeated. In the case of the examples illustrated in FIGS. 3 to 7, offset amount α is equal to maximum value 311 of predetermined range 307 when the update by the addition of predetermined distance 305 is performed once.

As illustrated in FIG. 8, suction rate R calculated every time the attachment operation of predetermined count number N is repeated is stored in data table 152 provided in EEPROM 144 in association with offset amount α and pick-up posture Δ at that time. In data table 152, numerals 1, 2, 3, . . . indicate the order in which the attachment operation of predetermined count number N is repeated.

Pick-up posture Δ is calculated by image processing section 145 performing image processing on the image data of image 150 captured by parts camera 34, that is, the image data of image 150 of electronic component 58 in a state of being picked up by suction nozzle 50. As illustrated in FIG. 9, for example, image processing section 145 compares and collates the pattern of electronic component 58 (represented by a solid line) actually projected on image 150 with the reference pattern of electronic component 58 (represented by a two-dot chain line) in a case where it is assumed that electronic component 58 is correctly picked up by suction nozzle 50. As a result, image processing section 145 obtains X-direction deviation ΔX indicating a distance difference in X-axis direction D1, Y-direction deviation ΔY indicating a distance difference in Y-axis direction D2, and Q-direction deviation ΔQ indicating an angle difference in the XY-plane (horizontal plane) view between specifying sections 60 of both patterns. In both patterns, for example, specifying section 60 is provided in a region where the portion of electronic component 58 picked up on the lower end face of suction nozzle 50 as originally intended is occupied in the XY-plane (horizontal plane) view. Then, image processing section 145 obtains standard deviation σ of X-direction deviation ΔX, Y-direction deviation ΔY, and Q-direction deviation ΔQ by using the image data of all images 150 captured by parts camera 34 as a population during the attachment operation of predetermined count number N is repeated. Further, image processing section 145 calculates a numerical value (that is, 3σ) obtained by multiplying standard deviation σ by three as pick-up posture Δ.

The image data of image 150 in which suction nozzle 50 fails to pick up electronic component 58 and only electronic component 58 is projected is excluded from the population to obtain standard deviation σ. In addition, the determination as to whether suction nozzle 50 has succeeded in or failed to pick up electronic component 58 which is described above may be performed using X-direction deviation ΔX, Y-direction deviation ΔY, and Q-direction deviation ΔQ as the determination material.

In data table 152 of EEPROM 144, in a case where there is only one highest suction rate β, pickup height 301 is changed to a height obtained by offset amount α associated with highest suction rate β, and the subsequent attachment operations are repeated. That is, pickup height 301 is fixed to a height distant from reference height 303 by a distance indicated by offset amount α associated with highest suction rate β. On the other hand, in a case where there are multiple highest suction rates β, pickup height 301 is changed to, for example, a height obtained by offset amount α specified based on pick-up posture Δ in addition to suction rate β, and the subsequent attachment operations are repeated. That is, pickup height 301 is fixed to a height distant from reference height 303 by a distance indicated by an offset amount α specified based on suction rate R and pick-up posture Δ. This specification may be performed by processing programmed in advance, or may be performed by an input operation or the like by an operator of mounting machine 16.

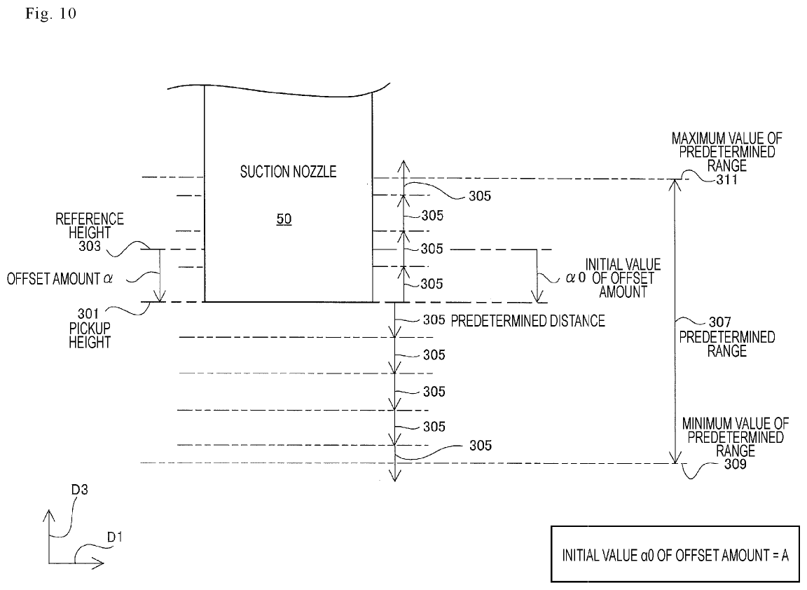

Examples illustrated in FIGS. 10 to 15 illustrate a case where initial value α0 of offset amount α is numerical value A other than ±0, unlike the examples illustrated in FIGS. 3 to 7 which are described above. The examples illustrated in FIGS. 10 to 15 will be described below. In the examples illustrated in FIGS. 10 to 15, numerical value A is a negative value.

First, as illustrated in FIG. 10, the attachment operation of predetermined count number N is repeated at pickup height 301 in a case where initial value α0 is substituted for offset amount α. Therefore, the attachment operation of predetermined count number N is repeated at pickup height 301 distant from reference height 303 by the distance indicated by offset amount α (that is, numerical value A of initial value α0).

In a case where suction rate β is larger than determination value γ, pickup height 301 is fixed to the current height, that is, the height distant from reference height 303 by the distance indicated by offset amount α, (that is, numerical value A of initial value α0), and the subsequent attachment operations are repeated. On the other hand, in a case where suction rate β is determination value γ or less, offset amount α is updated by subtracting predetermined distance 305 from offset amount α. Thereafter, the attachment operation of predetermined count number N is repeated at pickup height 301 in a case where offset amount α is updated.

Thereafter, in the same manner as in the examples illustrated in FIGS. 3 to 7 which are described above, the update of offset amount α by subtracting predetermined distance 305 and the attachment operation of predetermined count number N are repeated until suction rate β is larger than determination value γ and pickup height 301 is fixed to the current height.

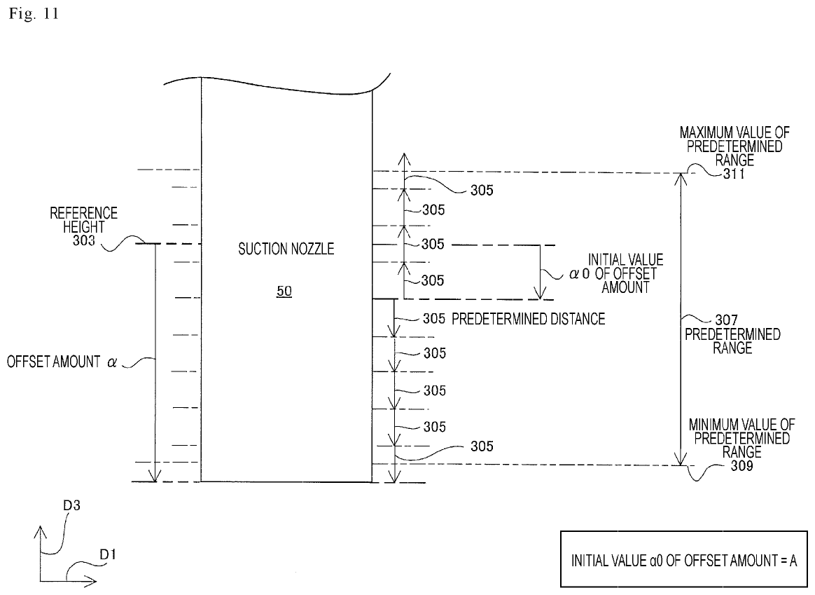

However, as illustrated in FIG. 11, in a case where offset amount α is less than minimum value 309 of predetermined range 307, the update of offset amount α is performed in the following manner. In the case of the examples illustrated in FIGS. 10 to 15, offset amount α is less than minimum value 309 of predetermined range 307 when the update by the subtraction of predetermined distance 305 is performed five times.

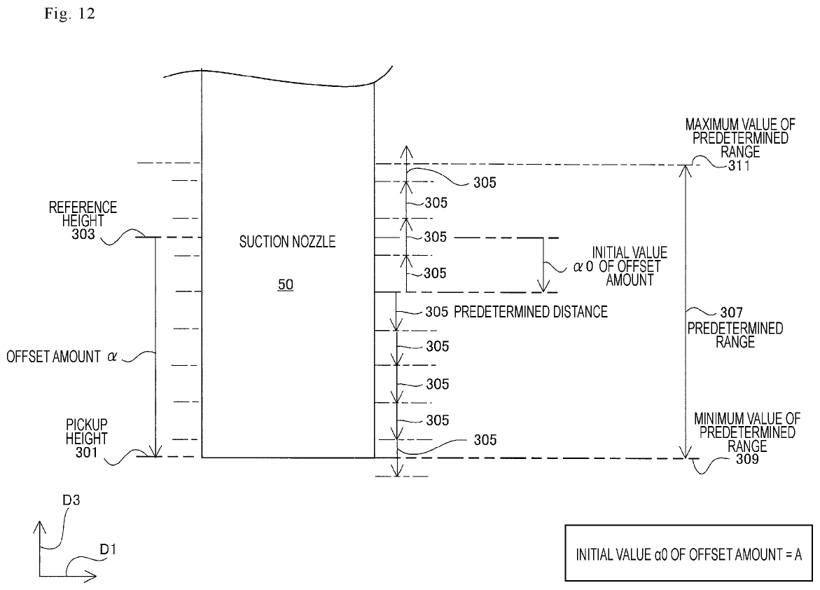

As illustrated in FIG. 12, minimum value 309 of predetermined range 307 is substituted for offset amount α. As a result, offset amount α is updated. Thereafter, the attachment operation of predetermined count number N is repeated at pickup height 301 in a case where offset amount α is updated, that is, at pickup height 301 distant from reference height 303 by the distance indicated by offset amount α (that is, minimum value 309 of predetermined range 307). Further, in this case, when suction rate β is not larger than determination value γ, the update of offset amount α is performed as follows.

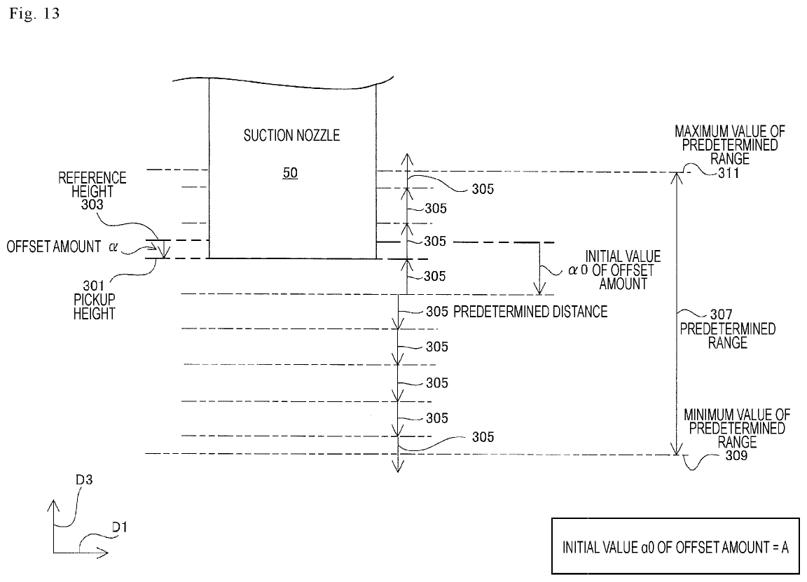

As illustrated in FIG. 13, the sum of initial value α0 and predetermined distance 305 is substituted for offset amount α. As a result, offset amount α is updated. As in the examples illustrated in FIGS. 10 to 15, in a case where initial value α0 of offset amount α is a numerical value other than 10, in a case where offset amount α is equal to minimum value 309 of predetermined range 307, and when suction rate β is not larger than determination value γ, the update of offset amount α is performed in the same manner. Thereafter, the attachment operation of predetermined count number N is repeated at pickup height 301 in a case where offset amount α is updated.

In a case where suction rate β is larger than determination value γ, pickup height 301 is fixed to the current height, that is, a height distant from reference height 303 by the distance indicated by offset amount α, and the subsequent attachment operations are repeated. On the other hand, in a case where suction rate R is determination value γ or less, offset amount α is updated by adding predetermined distance 305 to offset amount α. Thereafter, the attachment operation of predetermined count number N is repeated at pickup height 301 in a case where offset amount α is updated.

Thereafter, in the same manner as in the examples illustrated in FIGS. 3 to 7 which are described above, the update of offset amount α by the addition of predetermined distance 305 and the attachment operation of predetermined count number N are repeated until suction rate pi is larger than determination value γ and pickup height 301 is fixed to the current height. At this time, in a case where pickup height 301 in the case where offset amount α is updated is not equal to reference height 303, the following interrupt processing may be performed immediately before exceeding reference height 303. In the interrupt processing, pickup height 301 is in a state of being equal to reference height 303 regardless of the update of offset amount α by the addition of predetermined distance 305, and the attachment operation of predetermined count number N is repeated.

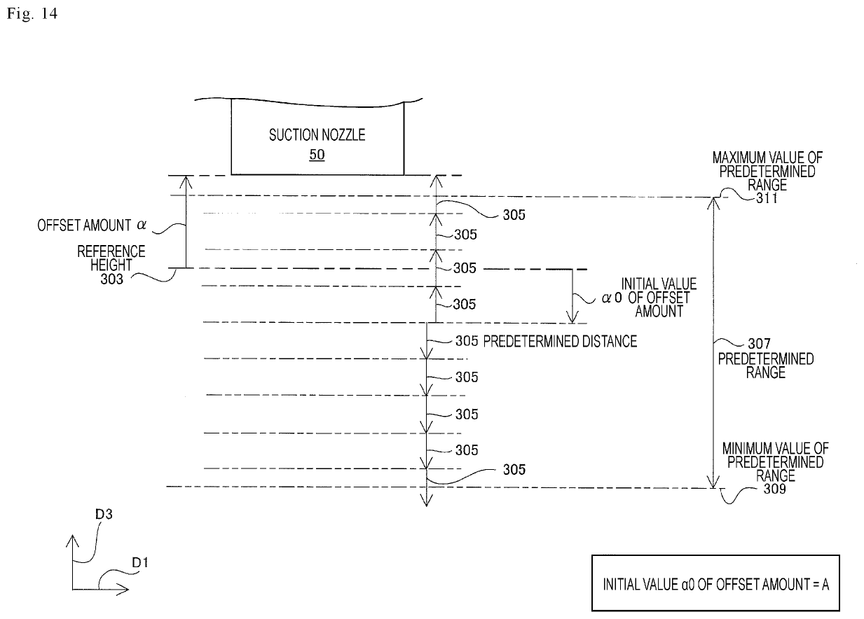

However, as illustrated in FIG. 14, in a case where offset amount α exceeds maximum value 311 of predetermined range 307, the update of offset amount α is performed in the following manner. In the case of the examples illustrated in FIGS. 10 to 15, offset amount α exceeds maximum value 311 of predetermined range 307 when the update by the addition of predetermined distance 305 is performed three times.

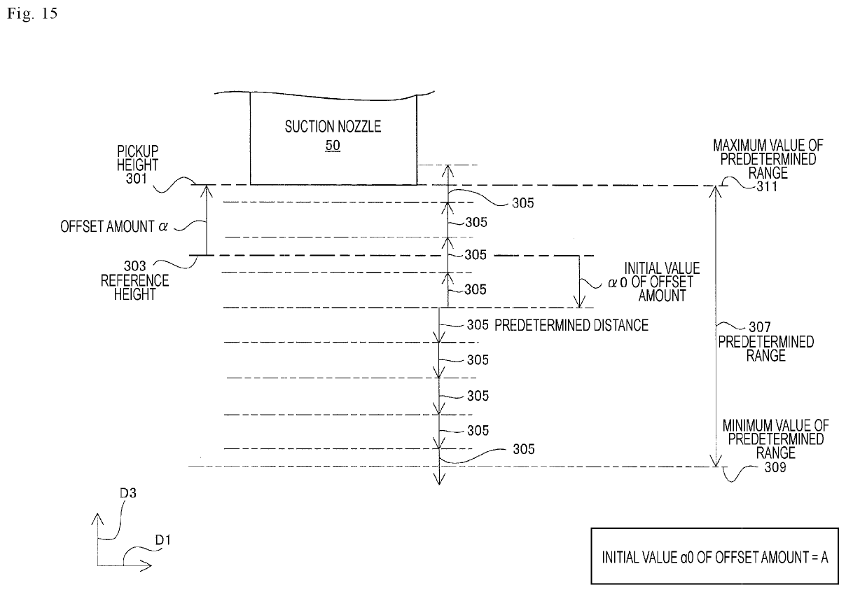

As illustrated in FIG. 15, maximum value 311 of predetermined range 307 is substituted for offset amount α. As a result, offset amount α is updated. Thereafter, the attachment operation of predetermined count number N is repeated at pickup height 301 in a case where offset amount α is updated, that is, at pickup height 301 distant from reference height 303 by the distance indicated by offset amount α (that is, maximum value 311 of predetermined range 307).

Further, in this case, when suction rate R is not larger than determination value γ, the update of offset amount α is stopped, and the subsequent attachment operations are repeated after pickup height 301 is changed based on the stored contents of data table 152 provided in EEPROM 144, similarly to the examples illustrated in FIGS. 3 to 7 which are described above. As in the examples illustrated in FIGS. 10 to 15, in a case where initial value α0 of offset amount α is a numerical value other than ±0, in a case where offset amount α is equal to maximum value 311 of predetermined range 307, even when suction rate β is not larger than determination value γ, the subsequent attachment operations are repeated after the change of pickup height 301 is similarly performed.

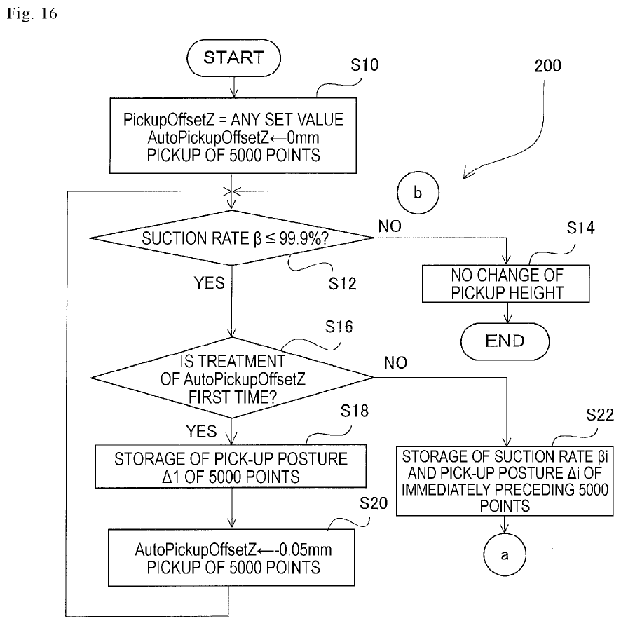

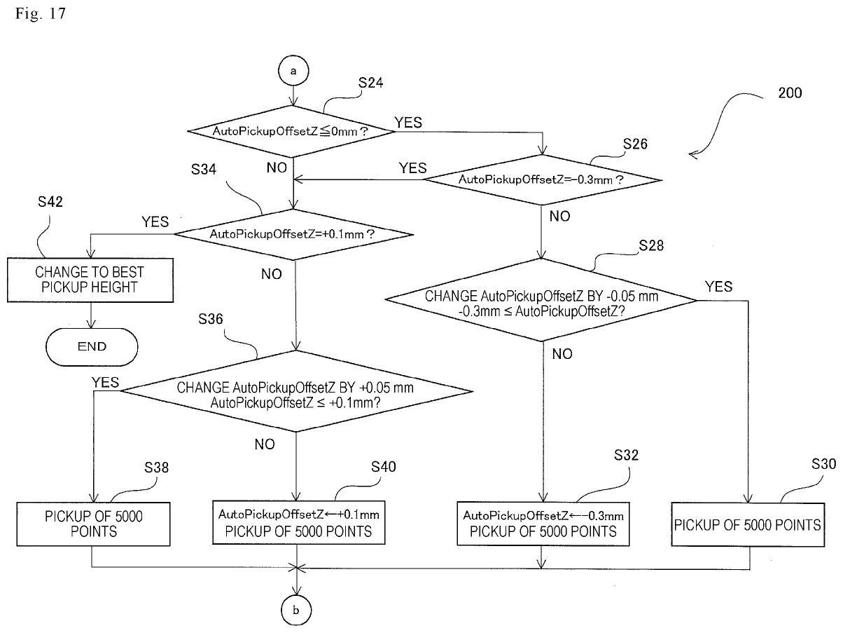

In mounting machine 16, for example, the change of pickup height 301 which is described above is performed by executing a control program for implementing first component mounting method 200 illustrated in flowcharts of FIGS. 16 and 17 by CPU 141 of control device 140. A flowchart of first component mounting method 200 will be described below. The numerical values used in the following description are merely examples, and are not limited to these. In addition, the control program for implementing first component mounting method 200 may be executed in a state not known to the operator of mounting machine 16, or may be executed in a state known to the operator of mounting machine 16.

The execution timings of first component mounting method 200 include, for example, when the attachment operation is started by mounting machine 16, when the support of tape feeder 70 is performed again in tape feeder support table 77, and the like. This also applies to the execution timings of second component mounting method 202 and third component mounting method 204 described later.

First, processing in step 10 (abbreviated as S) is performed. When this processing is performed, any numerical value set by the operator of mounting machine 16 through an input operation or the like has already been substituted for PickupOffsetZ (variable). PickupOffsetZ (variable) is used in a case where pickup height 301 is fixed to a height desired by the operator. In such a case, pickup height 301 is fixed to a height distant from reference height 303 by a distance indicated by PickupOffsetZ (variable). However, in the flowchart of first component mounting method 200, PickupOffsetZ (variable) is ignored.

In the processing of S10, 0 mm is substituted for AutoPickupOffsetZ (variable). AutoPickupOffsetZ (variable) corresponds to offset amount α which is described above. The 0 mm corresponds to initial value α0 of offset amount α which is described above. Further, in the processing of S10, pickup of 5000 points is performed at pickup height 301 distant from reference height 303 by a distance indicated by AutoPickupOffsetZ (variable). That is, as in the case illustrated in FIG. 3, pickup of 5000 points is performed at pickup height 301 equal to reference height 303. The pickup of 5000 points means that the pickup of electronic component 58 by suction nozzle 50 is performed 5000 times by repeatedly performing the attachment operation of predetermined count number N. In mounting machine 16, since mounting head 28 is provided with four suction nozzles 50, the pickup of electronic component 58 by suction nozzle 50 can be performed four times in one attachment operation. Therefore, in the present embodiment, the pickup of 5000 points is performed by repeating the attachment operation 1250 times.

In addition, with the pickup of 5000 points, image capturing of 5000 points is also performed. The image capturing of 5000 points means that the capturing of image 150 by parts camera 34 is performed 5000 times by repeatedly performing the attachment operation of predetermined count number N. This also applies to the pickup of 5000 points in each processing of S30, S32, S38, and S40 described later.

In the processing of S12, it is determined whether suction rate β calculated by performing the pickup of immediately preceding 5000 points is 99.9% or less. 99.9% corresponds to determination value γ which is described above. Here, in a case where suction rate β is larger than 99.9% (S12: NO), the processing of S14 is performed. In the processing of S14, pickup height 301 is fixed to the current height, and the subsequent attachment operations are repeated. As a result, the change of pickup height 301 by first component mounting method 200 is completed. On the other hand, in a case where suction rate β is 99.9% or less (S12: YES), the processing of S16 is performed. In order to enable suction rate β to be determined to be 99.9%, pickup of at least 1000 points (repetition of the attachment operation 250 times) may be performed.

In the processing of S16, it is determined whether the treatment of AutoPickupOffsetZ (variable) is the first time. The treatment of AutoPickupOffsetZ (variable) means setting pickup height 301 to the height obtained by substituted or updated AutoPickupOffsetZ (variable) when the pickup of 5000 points (that is, the repetition of the attachment operation 1250 times) is performed. Here, in a case where the treatment of AutoPickupOffsetZ (variable) is the first time (S16: YES), the processing of S18 is performed.

In the processing of S18, pick-up posture Δ1 of 5000 points is calculated and stored in EEPROM 144, pick-up posture Δ1 of 5000 points means pick-up posture Δ in a case where the pickup of 5000 points (that is, the repetition of the attachment operation 1250 times) is performed for the first time. Accordingly, the numerals in pick-up posture Δ1 indicate the order in which the pickup of 5000 points (that is, the repetition of the attachment operation 1250 times) is performed. In EEPROM 144, in addition to pick-up posture Δ1 in the same manner as data table 152 illustrated in FIG. 8, AutoPickupOffsetZ (variable)(corresponding to offset amount α) substituted for the processing of S10 and suction rate β calculated in the processing of S12 are stored in association with 1 of the numeral indicating the order in which the pickup of 5000 points (that is, the repetition of the attachment operation 1250 times) is performed. Thereafter, processing of S20 is performed.

In the processing of S20, −0.05 mm is substituted for AutoPickupOffsetZ (variable). Further, in the processing of S20, pickup of 5000 points (that is, the repetition of the attachment operation 1250 times) is performed at pickup height 301 distant from reference height 303 by the distance indicated by AutoPickupOffsetZ (variable). The processing of S20 corresponds to a case where AutoPickupOffsetZ (variable) is updated by subtracting 0.05 mm from AutoPickupOffsetZ (variable), that is, a case illustrated in the above-described FIG. 4. In such a case, 0.05 mm corresponds to predetermined distance 305 described above. Thereafter, the processing of S12 which is described above is performed.

On the other hand, in a case where the treatment of AutoPickupOffsetZ (variable) is performed two or larger times (S16: NO), the processing of S22 is performed. In the processing of S22, pick-up posture Δi at the pickup of immediately preceding 5000 points is calculated. Further, in the processing of S22, suction rate βi and pick-up posture Δi at the pickup of immediately preceding 5000 points are stored in EEPROM 144. A numeral indicating the order in which the pickup of 5000 points (that is, the repetition of the attachment operation 1250 times) is performed is substituted for subscript i of suction rate βi and pick-up posture Δi. Also, in the processing of S22, in EEPROM 144, in addition to suction rate si and pick-up posture Δi, in the same manner as in data table 152 illustrated in FIG. 8, AutoPickupOffsetZ (variable) (corresponding to offset amount α) subjected to the above-described treatment is stored in association with a numeral indicating the order in which the pickup of 5000 points (that is, the repetition of the attachment operation 1250 times) is performed. Thereafter, the processing of S24 illustrated in FIG. 17 is performed.

In the processing of S24, it is determined whether AutoPickupOffsetZ (variable) is 0 mm or less. Here, in a case where AutoPickupOffsetZ (variable) is larger than 0 mm (S24: NO), the processing of S34 which is described later is performed. On the other hand, in a case where AutoPickupOffsetZ (variable) is 0 mm or less (S24: YES), the processing of S26 is performed.

In the processing of S26, it is determined whether AutoPickupOffsetZ (variable) is −0.3 mm. The −0.3 mm corresponds to minimum value 309 of predetermined range 307 which is described above. Here, in a case where AutoPickupOffsetZ (variable) is −0.3 mm (S26: YES), the processing of S34 which is described later is performed. On the other hand, in a case where AutoPickupOffsetZ (variable) is 0 mm or less and larger than −0.3 mm (S26: NO), the processing of S28 is performed.

In the processing of S28, AutoPickupOffsetZ (variable) is changed by −0.05 mm. In other words, by subtracting 0.05 mm from AutoPickupOffsetZ (variable), AutoPickupOffsetZ (variable) is updated. Further, in the processing of S28, it is determined whether updated AutoPickupOffsetZ (variable) is −0.3 mm or larger.

Here, in a case where updated AutoPickupOffsetZ (variable) is −0.3 mm or larger (S28: YES), the processing of S30 is performed. In the processing of S30, the pickup of 5000 points (that is, the repetition of the attachment operation 1250 times) is performed at pickup height 301 distant from reference height 303 by the distance indicated by AutoPickupOffsetZ (variable). Thereafter, the processing of S12 illustrated in FIG. 16 is performed.

On the other hand, in a case where updated AutoPickupOffsetZ (variable) is less than −0.3 mm (S28: NO), the processing of S32 is performed. In a case where updated AutoPickupOffsetZ (variable) is less than −0.3 mm (S28: NO), for example, there is a case illustrated in FIG. 11 (however, initial value α0 of offset amount ac corresponding to AutoPickupOffsetZ (variable) is ±0).

In the processing of S32, −0.3 mm is substituted for AutoPickupOffsetZ (variable). Further, in the processing of S32, the pickup of 5000 points is performed at pickup height 301 distant from reference height 303 by the distance indicated by AutoPickupOffsetZ (variable). That is, as illustrated in the above-described FIG. 12, the pickup of 5000 points is performed at pickup height 301 distant from reference height 303 by minimum value 309 of predetermined range 307. Thereafter, the processing of S12 illustrated in FIG. 16 is performed.

Also, in the processing of S34, it is determined whether AutoPickupOffsetZ (variable) is +0.1 mm. The +0.1 mm corresponds to maximum value 311 of predetermined range 307 described above. Here, in a case where AutoPickupOffsetZ (variable) is +0.1 mm (S34: YES), the processing of S42 which is described later is performed. On the other hand, in a case where AutoPickupOffsetZ (variable) is less than +0.1 mm (S34: NO), the processing of S36 is performed.

In the processing of S36, AutoPickupOffsetZ (variable) is changed by +0.05 mm. In other words, AutoPickupOffsetZ (variable) is updated by adding 0.05 mm to AutoPickupOffsetZ (variable). However, in a case where 0.05 mm is first added to AutoPickupOffsetZ (variable), AutoPickupOffsetZ (variable) is updated by substituting the sum of 0 mm and +0.05 mm that are substituted for the processing of S10 which is described above. In other words, AutoPickupOffsetZ (variable) is updated by adding 0.05 mm to 0 mm which is the initial value of AutoPickupOffsetZ (variable). Such a case corresponds to the case illustrated in FIG. 6. Further, in the processing of S36, it is determined whether updated AutoPickupOffsetZ (variable) is +0.1 mm or less.

Here, when updated AutoPickupOffsetZ (variable) is +0.1 mm or less (S36: YES), the processing of S38 is performed. In the processing of S38, the pickup of 5000 points (that is, the repetition of the attachment operation 1250 times) is performed at pickup height 301 distant from reference height 303 by the distance indicated by AutoPickupOffsetZ (variable). Thereafter, the processing of S12 illustrated in FIG. 16 is performed.

On the other hand, in a case where updated AutoPickupOffsetZ (variable) is larger than +0.1 mm (S36: NO), the processing of S40 is performed. In a case where updated AutoPickupOffsetZ (variable) is larger than +0.1 mm (S36: NO), for example, there is a case illustrated in the above-described FIG. 14 (however, initial value α0 of offset amount α corresponding to AutoPickupOffsetZ (variable) is ±0).

In the processing of S40, +1.0 mm is substituted for AutoPickupOffsetZ (variable). Further, in the processing of S40, the pickup of 5000 points is performed at pickup height 301 distant from reference height 303 by the distance indicated by AutoPickupOffsetZ (variable). That is, as illustrated in FIG. 15 which is described above, the pickup of 5000 points is performed at pickup height 301 distant from reference height 303 by maximum value 311 of predetermined range 307. Thereafter, the processing of S12 illustrated in FIG. 16 is performed.

On the other hand, in the processing of S42, the update of AutoPickupOffsetZ (variable) is stopped, and after pickup height 301 is changed to the optimal height based on the stored content of data table 152 of EEPROM 144, the subsequent attachment operations are repeated as described above. In other words, in a case where there is only one highest suction rate β in data table 152 of EEPROM 144, pickup height 301 is changed to the height obtained by AutoPickupOffsetZ (variable) associated with highest suction rate β, and the subsequent attachment operations are repeated. On the other hand, in a case where there are multiple highest suction rates β, pickup height 301 is changed to, for example, the height obtained by AutoPickupOffsetZ (variable) specified based on pick-up posture Δ in addition to suction rate β, and the subsequent attachment operations are repeated. As a result, the change of pickup height 301 by second component mounting method 202 is completed.

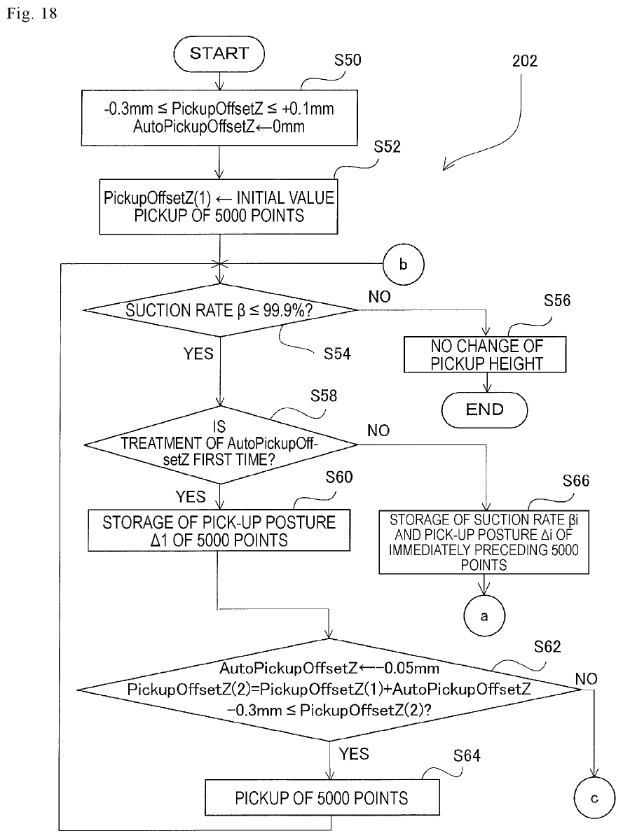

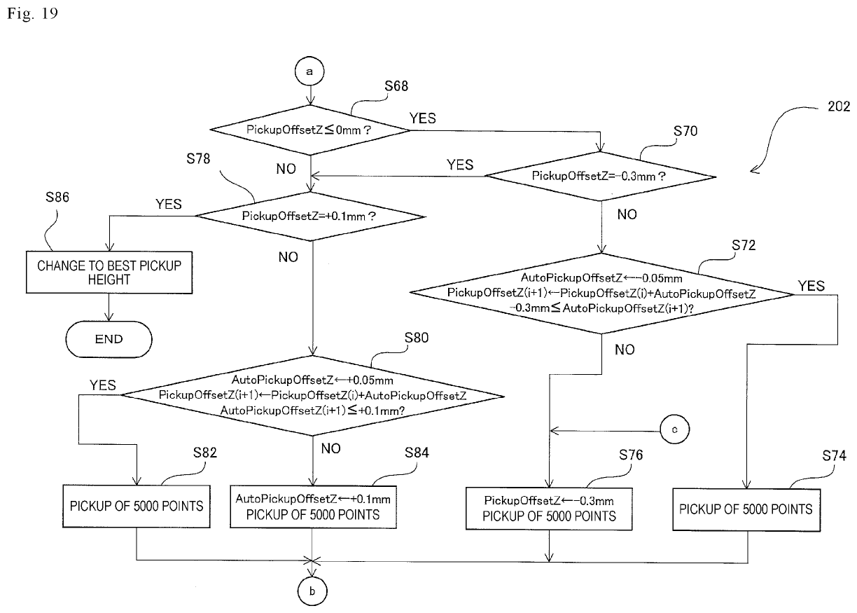

In mounting machine 16, for example, the change of pickup height 301 which is described above is performed by executing a control program for implementing second component mounting method 202 illustrated in the flowcharts of FIGS. 18 and 19 by CPU 141 of control device 140. The flowchart of second component mounting method 202 will be described below. The numerical values used in the following description are merely examples, and are not limited to these.

First, processing of S50 is performed. When this processing is performed, a numerical value of −0.3 mm or larger and +0.1 mm or less is already in a state of being substituted for PickupOffsetZ (variable) by setting by the operator of mounting machine 16 with input operation or the like. PickupOffsetZ (variable) is used in a case where pickup height 301 is fixed to a height desired by the operator. In such a case, pickup height 301 is fixed to a height distant from reference height 303 by a distance indicated by PickupOffsetZ (variable).

However, in the flowchart of second component mounting method 202, PickupOffsetZ (variable) is changed by overwriting regardless of the input operation of the operator or the like. Therefore, it is preferable that the control program for implementing second component mounting method 202 is executed in a state not known to the operator of mounting machine 16. PickupOffsetZ (variable) corresponds to offset amount α which is described above. In the flowchart of second component mounting method 202, the number appended to PickupOffsetZ (variable) indicates the number of times PickupOffsetZ (variable) is overwritten.

In the processing of S50, 0 mm is substituted for AutoPickupOffsetZ (variable).

In the processing of S52, an initial value is substituted for PickupOffsetZ(1) (variable). PickupOffsetZ (variable) is overwritten with PickupOffsetZ(1)(variable). The initial value is a numerical value substituted for PickupOffsetZ (variable) in the processing of S50 which is described above. The initial value corresponds to initial value α0 of offset amount α which is described above. In addition, in the processing of S52, the pickup of 5000 points is performed at pickup height 301 distant from reference height 303 by the distance indicated by overwritten PickupOffsetZ (variable). That is, as in the case illustrated in the above-described FIG. 10, the pickup of 5000 points is performed at pickup height 301 distant from reference height 303 by the distance (that is, the initial value) indicated by PickupOffsetZ (variable). The pickup of 5000 points is the same as in the case of first component mounting method 200 illustrated in the flowcharts in FIGS. 16 and 17 which are described above.

In addition, with the pickup of 5000 points, image capturing of 5000 points is also performed. This also applies to the pickup of 5000 points in each processing of S64, S74, S76, S82, and S84 which is described later. The image of 5000 points is the same as in the case of first component mounting method 200 illustrated in the flowcharts in FIGS. 16 and 17 described above.

In the processing of S54, it is determined whether suction rate β calculated by performing the pickup of immediately preceding 5000 points is 99.9% or less. 99.9% corresponds to determination value γ which is described above. Here, in a case where suction rate β is larger than 99.9% (S54: NO), the processing of S56 is performed. In the processing of S56, pickup height 301 is fixed to the current height, and the subsequent attachment operations are repeated. As a result, the change of pickup height 301 by second component mounting method 202 is completed. On the other hand, in a case where suction rate β is 99.9% or less (S54: YES), the processing of S58 is performed. In order to enable suction rate S to be determined to be 99.9%, the pickup of at least 1000 points (repetition of the attachment operation 250 times) may be performed in the same manner as in the case of first component mounting method 200 illustrated in the flowcharts of FIGS. 16 and 17 which are described above.

In the processing of S58, it is determined whether the treatment of AutoPickupOffsetZ (variable) is the first time. The treatment of AutoPickupOffsetZ (variable) means setting pickup height 301 to the height obtained by PickupOffsetZ (variable) overwritten by the calculation using AutoPickupOffsetZ (variable) when the pickup of 5000 points (that is, the repetition of the attachment operation 1250 times) are performed. In the flowchart of second component mounting method 202, the number of treatments of AutoPickupOffsetZ (variable) is the same as the number appended to PickupOffsetZ (variable), that is, the number of times PickupOffsetZ (variable) is overwritten. Here, in a case where the treatment of AutoPickupOffsetZ (variable) is the first time (S58: YES), the processing of S60 is performed.

In the processing of S60, pick-up posture Δ1 of 5000 points is calculated. Further, in the processing of S60, pick-up posture Δ1 of 5000 points is stored in EEPROM 144, pick-up posture Δ1 of 5000 points means pick-up posture Δ in a case where the pickup of 5000 points (that is, the repetition of the attachment operation 1250 times) is performed for the first time. Accordingly, the numerals in pick-up posture Δ1 indicate the order in which the pickup of 5000 points (that is, the repetition of the attachment operation 1250 times) is performed. In addition, in the flowchart of second component mounting method 202, the number in pick-up posture Δ1 also represents a number appended to PickupOffsetZ (variable), that is, the number of times PickupOffsetZ (variable) is overwritten. In EEPROM 144, in addition to pick-up posture Δ1, in the same manner as data table 152 illustrated in above-described FIG. 8, PickupOffsetZ(1) (variable) in which PickupOffsetZ (variable) (corresponding to offset amount α) is overwritten in the processing of S52, and suction rate pi calculated in the processing of S54 are stored in association with 1 of the numeral indicating the order in which the pickup of 5000 points is performed (that is, the repetition of the attachment operation 1250 times). Thereafter, processing of S62 is performed.

In the processing of S62, −0.05 mm is substituted for AutoPickupOffsetZ (variable). Further, in the processing of S62, PickupOffsetZ (variable) is overwritten with PickupOffsetZ(2) (variable) obtained by adding AutoPickupOffsetZ (variable) to PickupOffsetZ(1) (variable). As a result, PickupOffsetZ (variable) is updated. Further, in the processing of S62, it is determined whether PickupOffsetZ(2) (variable) is −0.3 mm or larger. The −0.3 mm corresponds to minimum value 309 of predetermined range 307 which is described above.

Here, in a case where PickupOffsetZ(2)(variable) is less than −0.3 mm (S62: NO), processing of S76 in FIG. 19 which is described later is performed. On the other hand, in a case where PickupOffsetZ(2) (variable) is −0.3 mm or larger (S62: YES), processing of S64 is performed.

In the processing of S64, the pickup of 5000 points (that is, the repetition of the attachment operation 1250 times) is performed at pickup height 301 distant from reference height 303 by the distance indicated by overwritten PickupOffsetZ (variable). The processing of S64 corresponds to a case where PickupOffsetZ (variable) is updated by subtracting 0.05 mm from PickupOffsetZ (variable), that is, a case illustrated in the above-described FIG. 4. In such a case, 0.05 mm corresponds to predetermined distance 305 described above. Thereafter, the processing of S54 described above is performed.

On the other hand, in a case where the treatment of AutoPickupOffsetZ (variable) is performed two or larger times (S58: NO), processing of S66 is performed. In the processing of S66, suction rate βi at the pickup of immediately preceding 5000 points is calculated. Further, in the processing of S66, suction rate Pi and pick-up posture Δi at the pickup of immediately preceding 5000 points are stored in EEPROM 144. In EEPROM 144, in addition to suction rate Pi and pick-up posture Δi, in the same manner as data table 152 illustrated in FIG. 8 which is described above, PickupOffsetZ(i) (variable) in which PickupOffsetZ (variable) (corresponding to offset amount α) is overwritten by the above-described treatment is stored in association with a number indicating the order in which the pickup of 5000 points is performed (that is, the repetition of the attachment operation 1250 times). The number indicating the order in which the pickup of 5000 points (that is, the repetition of the attachment operation 1250 times) is performed is substituted for the subscript i of suction rate Pi, pick-up posture Δi, and PickupOffsetZ(i) (variable). In addition, as described above, the numerals substituted for the subscripts i in suction rate Pi, pick-up posture Δi, and PickupOffsetZ(i) (variable) also indicate the number of times PickupOffsetZ (variable) is overwritten in the flowchart of second component mounting method 202. Thereafter, processing of S68 illustrated in FIG. 19 is performed.

In the processing of S68, it is determined whether PickupOffsetZ (variable) is 0 mm or less. Here, in a case where PickupOffsetZ (variable) is larger than 0 mm (S68: NO), processing of S78 which is described later is performed. On the other hand, in a case where PickupOffsetZ (variable) is 0 mm or less (68: YES), processing of S70 is performed.

In the processing of S70, it is determined whether PickupOffsetZ (variable) is −0.3 mm. Here, in a case where PickupOffsetZ (variable) is −0.3 mm (S70: YES), processing of S78 which is described later is performed. On the other hand, in a case where PickupOffsetZ (variable) is 0 mm or less and larger than −0.3 mm (S70: NO), processing of S72 is performed.

In the processing of S72, −0.05 mm is substituted for AutoPickupOffsetZ (variable). Further, in the processing of S72, PickupOffsetZ (variable) is overwritten with PickupOffsetZ(i+1) (variable) obtained by adding AutoPickupOffsetZ (variable) to PickupOffsetZ(i) (variable). As a result, PickupOffsetZ (variable) is updated. Further, in the processing of S72, it is determined whether PickupOffsetZ(i+1) (variable) is −0.3 mm or larger.

Here, in a case where PickupOffsetZ(i+1) (variable) is −0.3 mm or larger (S72: YES), the processing of S74 is performed. In the processing of S74, the pickup of 5000 points (that is, the repetition of the attachment operation 1250 times) is performed at pickup height 301 distant from reference height 303 by the distance indicated by PickupOffsetZ (variable). Thereafter, the processing of S54 illustrated in FIG. 18 is performed.

On the other hand, in a case where PickupOffsetZ(i+1)(variable) is less than −0.3 mm (S72: NO), the processing of S76 is performed. In a case where PickupOffsetZ(i+1) (variable) is less than −0.3 mm (S72: NO), for example, there is a case illustrated in FIG. 11 which is described above (however, initial value α0 of offset amount α corresponding to PickupOffsetZ (variable) is ±0).

In the processing of S76, −0.3 mm is substituted for PickupOffsetZ (variable). Further, in the processing of S76, the pickup of 5000 points is performed at pickup height 301 distant from reference height 303 by the distance indicated by PickupOffsetZ (variable). That is, as illustrated in the above-described FIG. 12, the pickup of 5000 points is performed at pickup height 301 distant from reference height 303 by minimum value 309 of predetermined range 307. Thereafter, the processing of S54 illustrated in FIG. 18 is performed.

On the other hand, in the processing of S78, it is determined whether PickupOffsetZ (variable) is +0.1 mm. The +0.1 mm corresponds to maximum value 311 of predetermined range 307 described above. Here, in a case where PickupOffsetZ (variable) is +0.1 mm (S78: YES), processing of S86 which is described later is performed. On the other hand, in a case where PickupOffsetZ (variable) is less than +0.1 mm (S78: NO), processing of S80 is performed.

In the processing of S80, +0.05 mm is substituted for AutoPickupOffsetZ (variable). Further, in the processing of S80, PickupOffsetZ (variable) is overwritten with PickupOffsetZ(i+1) (variable) obtained by adding AutoPickupOffsetZ (variable) to PickupOffsetZ(i) (variable). As a result, PickupOffsetZ (variable) is updated. However, in a case where AutoPickupOffsetZ (variable) of +0.05 mm is added for the first time, PickupOffsetZ(i+1) (variable) is obtained by substituting the sum of the initial value to be substituted for the processing of S52 which is described above and AutoPickupOffsetZ (variable) of +0.05 mm. In other words. PickupOffsetZ (variable) is updated by adding 0.05 mm to the initial value of PickupOffsetZ (variable). Such a case corresponds to the case illustrated in FIG. 13 which is described above. Further, in the processing of S80, it is determined whether PickupOffsetZ(i+1) (variable) is +0.1 mm or less.

Here, in a case where PickupOffsetZ(i+1) (variable) is +0.1 mm or less (S80: YES), processing of S84 is performed. In the processing of S84, the pickup of 5000 points (that is, the repetition of the attachment operation 1250 times) is performed at pickup height 301 distant from reference height 303 by the distance indicated by PickupOffsetZ (variable). Thereafter, the processing of S54 illustrated in FIG. 18 is performed.

On the other hand, in a case where PickupOffsetZ(i+1) (variable) is larger than +0.1 mm (S80: NO), processing of S84 is performed. In a case where PickupOffsetZ(i+1) (variable) is larger than +0.1 mm (S80: NO), for example, there is a case illustrated in FIG. 14 which is described above (however, initial value α0 of offset amount α corresponding to PickupOffsetZ (variable) is ±0).

In the processing of S84, +0.1 mm is substituted for PickupOffsetZ (variable). Further, in the processing of S84, the pickup of 5000 points is performed at pickup height 301 distant from reference height 303 by the distance indicated by PickupOffsetZ (variable). That is, as illustrated in FIG. 15 which is described above, the pickup of 5000 points is performed at pickup height 301 distant from reference height 303 by maximum value 311 of predetermined range 307. Thereafter, the processing of S54 illustrated in FIG. 18 is performed.

On the other hand, in the processing of S86, the update of PickupOffsetZ (variable) by the overwriting is stopped, and after pickup height 301 is changed to the optimal height based on the stored content of data table 152 of EEPROM 144, the subsequent attachment operations are repeated as described above. In other words, in a case where there is only one highest suction rate pi in data table 152 of EEPROM 144, pickup height 301 is changed to the height obtained by PickupOffsetZ (variable) associated with highest suction rate β, and the subsequent attachment operations are repeated. On the other hand, in a case where there are multiple highest suction rates β, pickup height 301 is changed to, for example, the height obtained by PickupOffsetZ (variable) specified based on pick-up posture Δ in addition to suction rate β, and the subsequent attachment operations are repeated. As a result, the change of pickup height 301 by second component mounting method 202 is completed.

In mounting machine 16, for example, the change of pickup height 301 which is described above is performed by executing a control program for implementing third component mounting method 204 illustrated in the flowcharts in FIGS. 20 to 22 by CPU 141 of control device 140. The flowchart of third component mounting method 204 will be described below.

First, processing of S100 is performed. In the processing of S100, initial value α0 is substituted for offset amount α. Offset amount α at this time is illustrated in, for example, the above-described FIG. 3 or 10. Thereafter, processing of S102 is performed. In the processing of S102, the attachment operation of predetermined count number N is repeated at pickup height 301 distant from reference height 303 by the distance indicated by offset amount α. In mounting machine 16, since mounting head 28 is provided with four suction nozzles 50, whenever the attachment operation is performed once, the pickup of electronic component 58 by suction nozzle 50 and the capturing of image 150 by parts camera 34 are performed four times. Therefore, in the processing of S102, the pickup of electronic component 58 by suction nozzle 50 and the capturing of image 150 by parts camera 34 are performed N×4 times each. Thereafter, processing of S104 is performed.

In the processing of S104, suction rate β and pick-up posture Δ are calculated. Further, as illustrated in FIG. 8, suction rate β and pick-up posture Δ are stored in data table 152 of EEPROM 144 in association with offset amount α and the number indicating the order in which the attachment operation of predetermined count number N is repeated. Thereafter, processing of S106 is performed.

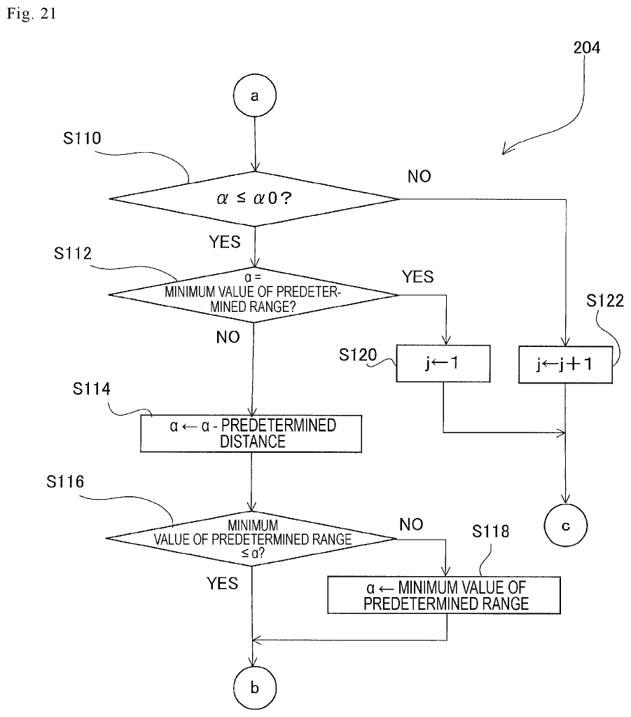

In the processing of S106, it is determined whether suction rate β is determination value γ or less. Here, when suction rate β is larger than determination value γ (S106: NO), the first continuation processing of S108 is performed. In the first continuation processing of S108, pickup height 301 is fixed to the current height, and the subsequent attachment operations are repeated. As a result, the change of pickup height 301 by second component mounting method 202 is completed. On the other hand, in a case where suction rate β is determination value γ or less (S106: YES), processing of S110 illustrated in FIG. 21 is performed.

In the processing of S110, it is determined whether offset amount α is initial value α0 or less. Here, in a case where offset amount α is larger than initial value α0 (S110: NO), processing of S122 which is described later is performed. On the other hand, in a case where offset amount α is initial value α0 or less (S110: YES), processing in step S112 is performed.

In the processing of S112, it is determined whether offset amount α is equal to minimum value 309 of predetermined range 307. Here, in a case where offset amount α is equal to minimum value 309 of predetermined range 307 (S112: YES), the processing of S120 which is described later is performed. On the other hand, in a case where offset amount α is initial value α0 or less but larger than minimum value 309 of predetermined range 307 (S112: NO), processing of S114 is performed.

In the processing of S114, offset amount α is updated by subtracting predetermined distance 305 from offset amount α. Offset amount α at this time is illustrated in, for example, the above-described FIGS. 4 and 5 or FIG. 11. Thereafter, processing of S116 is performed.

In the processing of S116, it is determined whether updated offset amount α is minimum value 309 or larger of predetermined range 307. Here, in a case where updated offset amount α is minimum value 309 or larger of predetermined range 307 (S116: YES), the processing of S102 illustrated in FIG. 20 which is described above is performed. Offset amount α in this case is illustrated in, for example, FIGS. 4 and 5 which are described above. On the other hand, in a case where updated offset amount α is less than minimum value 309 of predetermined range 307 (S116: NO), the processing of S118 is performed. Offset amount α in this case is illustrated in, for example, FIG. 11 which is described above.

In the processing of S118, minimum value 309 of predetermined range 307 is substituted for offset amount α. Offset amount α in this case is illustrated in, for example, FIG. 12 which is described above. Thereafter, the processing of S102 illustrated in FIG. 20 which is described above is performed.

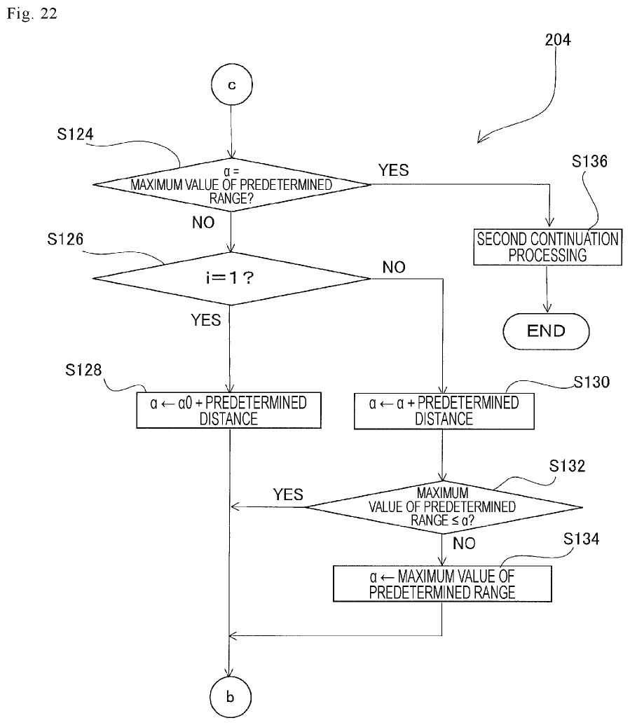

On the other hand, in the processing of S120, 1 is substituted for variable i. Thereafter, processing of S124 illustrated in FIG. 22 is performed. In the processing of S122, variable i is incremented. Thereafter, processing of S124 illustrated in FIG. 22 is performed.

In the processing of S124, it is determined whether updated offset amount α is equal to maximum value 311 of predetermined range 307. Here, in a case where updated offset amount α is equal to maximum value 311 of predetermined range 307 (S124: YES), the second continuation processing of S136 which is described later is performed. On the other hand, in a case where updated offset amount α is larger than initial value α0 but less than maximum value 311 of predetermined range 307 (S124: NO), processing of S126 is performed.

In the processing of S126, it is determined whether variable i is 1. Here, in a case where variable i is 1 (S126: YES), processing of S128 is performed. In the processing of S128, offset amount α is updated by substituting the sum of initial value α0 and predetermined distance 305 for offset amount α. Offset amount α at this time is illustrated in, for example, FIG. 6 or 13 which is described above. Thereafter, the processing of S102 illustrated in FIG. 20 which is described above is performed.

On the other hand, in a case where variable i is 2 or larger (S126: NO), processing of S130 is performed. In the processing of S130, offset amount α is updated by adding predetermined distance 305 to offset amount α. Offset amount α at this time is illustrated in, for example, FIG. 7 or FIG. 14. Thereafter, processing of S132 is performed.

In the processing of S132, it is determined whether updated offset amount α is maximum value 311 or less of predetermined range 307. Here, in a case where updated offset amount α is maximum value 311 or less of predetermined range 307 (S132: YES), the processing of S102 illustrated in FIG. 20 which is described above is performed. Offset amount α in this case is illustrated in, for example, FIG. 7 which is described above. On the other hand, in a case where updated offset amount α is larger than maximum value 311 of predetermined range 307 (S132: NO), processing of S134 is performed. Offset amount α in this case is illustrated in, for example, FIG. 14 which is described above.

In the processing of S134, maximum value 311 of predetermined range 307 is substituted for offset amount α. Offset amount α in this case is illustrated in, for example, FIG. 15 which is described above. Thereafter, the processing of S102 illustrated in FIG. 20 which is described above is performed.

On the other hand, in the second continuation processing of S136, the update of offset amount α is stopped, and after pickup height 301 is changed to the optimal height based on the stored content of data table 152 of EEPROM 144, the subsequent attachment operations are repeated as described above. In other words, in a case where there is only one highest suction rate β in data table 152 of EEPROM 144, pickup height 301 is changed to the height obtained by offset amount α associated with highest suction rate β, and the subsequent attachment operations are repeated. On the other hand, in a case where there are multiple highest suction rates β, pickup height 301 is changed to, for example, a height obtained by offset amount α specified based on pick-up posture Δ in addition to suction rate β, and the subsequent attachment operations are repeated. As a result, the change of pickup height 301 by third component mounting method 204 is completed.

In the flowchart of third component mounting method 204, when offset amount α is regarded as AutoPickupOffsetZ (variable), the flowchart of third component mounting method 204 corresponds to the flowchart of first component mounting method 200 illustrated in FIGS. 16 and 17 which are described above. In the flowchart of third component mounting method 204, when offset amount α is regarded as PickupOffsetZ (variable) and initial value α0 and predetermined distance 305 are regarded as AutoPickupOffsetZ (variable), the flowchart of third component mounting method 204 corresponds to the flowchart of second component mounting method 202 illustrated in FIGS. 18 and 19 which are described above.

As described in detail above, mounting machine 16 of the present embodiment can find pickup height 301 suitable for the attachment operation based on the suction rate β, which is the statistical probability that an event in which the pickup of electronic component 58 is successful occurs, and perform the attachment operation at found pickup height 301, during repeating the attachment operation for attaching electronic component 58 picked up by suction nozzle 50 to circuit board 44 at pickup height 301.

In the present embodiment, mounting machine 16 is an example of the component mounting machine. Parts camera 34 is an example of the camera. Circuit board 44 is an example of the board. Suction nozzle 50 is an example of the suction tool. Nozzle lifting and lowering device 54 is an example of the moving mechanism. Electronic component 58 is an example of the component. EEPROM 144 is an example of the memory. First component mounting method 200, second component mounting method 202, and the third component mounting method are examples of the component mounting method. X-direction deviation ΔX, Y-direction deviation ΔY, and Q-direction deviation ΔQ are examples of data indicating the component posture.

In the flowchart of first component mounting method 200, each processing of S10, S20, S30, S32, S38, and S40 is an example of the attempt section, the acquiring section, and the attempting step. The processing of S12 is an example of the first calculation section and the calculating step. The processing of S14 is an example of the first continuation section and the continuing step. Each processing of S18 and S22 is an example of the storage section and the second calculation section. Each processing of S28 and S36 is an example of the updating section and the updating step. The processing of S42 is an example of the second continuation section.

In the flowchart of second component mounting method 202, each processing of S52, S64, S74, S76, S82, and S84 is an example of the attempt section, the acquiring section, and the attempting step. The processing of S54 is an example of the first calculation section and the calculating step. The processing of S56 is an example of the first continuation section and the continuing step. Each processing of S60 and S66 is an example of the storage section and the second calculation section. Each processing of S62, S72, and S80 is an example of the updating section and the updating step. The processing of S86 is an example of the second continuation section.

In the flowchart of third component mounting method 204, the processing of S102 is an example of the attempt section, the acquiring section, and the attempting step. The processing of S104 is an example of the first calculation section, the storage section, the second calculation section, and the calculating step. The first continuation processing of S108 is an example of the first continuation section and the continuing step. Each processing of S114, S128, and S130 is an example of the updating section and the updating step. The second continuation processing of S136 is an example of the second continuation section.

The present disclosure is not limited to the above-described embodiments, and various changes may occur without departing from the gist thereof. For example, each of component mounting methods 200, 202, and 204 may be repeatedly executed without a lapse of time, or may be executed again with a lapse of a predetermined time period.

In third component mounting method 204, contrary to the embodiments which are described above, offset amount α may be first subsequently updated from initial value α0 of offset amount α to maximum value 311 of predetermined range 307 at intervals of predetermined distance 305, and then subsequently updated from initial value α0 of offset amount α to minimum value 309 of predetermined range 307 at intervals of predetermined distance 305. This also applies to AutoPickupOffsetZ (variable) in first component mounting method 200 and PickupOffsetZ (variable) in second component mounting method 202.

In third component mounting method 204, each time the subtraction in the processing of S114 or the addition in the processing of S128 and S130 is performed, offset amount α or the predetermined distance to be added or subtracted to or from initial value α0 thereof may be changed. This also applies to 0.05 mm that is added or subtracted to or from AutoPickupOffsetZ (variable) in first component mounting method 200. For example, each time the addition or subtraction is performed, the numerical value to be added or subtracted to or from AutoPickupOfFsetZ (variable) is changed to 0.03 mm, 0.06 mm, 0.05 mm, 0.04 mm, . . . . Further, this also applies to −0.05 mm and +0.05 mm to be substituted for AutoPickupOffsetZ (variable) in second component mounting method 202. For example, each time AutoPickupOffsetZ (variable) is substituted, it is changed to −0.04 mm, −0.05 mm, −0.03 mm, −0.06 mm, . . . , or to +0.06 mm, +0.04 mm, +0.05 mm, +0.03 mm, . . . .

### REFERENCE SIGNS LIST

16: mounting machine. 34: parts camera, 44: circuit board, 50: suction nozzle, 54: nozzle lifting and lowering device, 58: electronic component, 114: EEPROM, 150: image, 200: first component mounting method, 202: second component mounting method, 204: third component mounting method, 301: pickup height, 303: reference height, 305: predetermined distance, 307: predetermined range, 309: minimum value of predetermined range, 311: maximum value of predetermined range, N: predetermined count number, S108: first continuation processing, S136: second continuation processing, α: offset amount, α0: initial value of offset amount, β: suction rate, γ: determination value, ΔX: X-direction deviation, ΔY: Y-direction deviation, ΔQ: Q-direction deviation, σ: standard deviation

1. A component mounting machine for executing an attachment operation for attaching a component to a board, the component mounting machine comprising:
a suction tool configured to pick up the component at a pickup height distant from a reference height by a distance indicated by an offset amount;
a moving mechanism configured to move the suction tool to the pickup height;
an attempt section configured to perform the attachment operation a predetermined count number,
a first calculation section configured to calculate a suction rate indicating a ratio of successfully picking up the component by the suction tool during the attachment operation of the predetermined count number, and
an updating section configured to update the offset amount within a predetermined range by adding or subtracting a predetermined distance to or from the offset amount when the suction rate is less than a determination value, and further repeat the attempt section and the first calculation section.

2. The component mounting machine according to claim 1, further comprising:
a first continuation section configured to fix the pickup height to a height distant from the reference height by a distance indicated by the offset amount and continue the attachment operation when the suction rate is larger than the determination value.

3. The component mounting machine according to claim 1,
wherein the updating section subsequently performs the subtraction to subsequently update the offset amount between an initial value of the offset amount and a minimum value of the predetermined range, and then subsequently performs the addition to subsequently update the offset amount between the initial value of the offset amount and a maximum value of the predetermined range.

4. The component mounting machine according to claim 3, further comprising:
a memory;
a storage section configured to store the suction rate and the offset amount in association with each other in the memory, each time the attempt section performs the attachment operation the predetermined count number, and
a second continuation section configured to perform processing on behalf of the updating section when the offset amount matches the maximum value of the predetermined range or exceeds the maximum value, when the suction rate is less than the determination value,
wherein the second continuation section fixes the pickup height to a height distant from the reference height by a distance indicated by the offset amount stored in association with a best suction rate in the memory, and continues the attachment operation.

5. The component mounting machine according to claim 4, further comprising:
a camera configured to capture an image of a state where the suction tool picks up the component;
an acquiring section configured to acquire data indicating a posture of the component based on the image; and
a second calculation section configured to calculate a standard deviation of data indicating the posture of the component based on the attachment operation performed in the attempt section for the predetermined count number as a population,
wherein the storage section stores the standard deviation by being associated with the suction rate and the offset amount, and
the second continuation section fixes the pickup height to a height distant from the reference height by a distance determined based on the suction rate, the offset amount, and the standard deviation stored in the storage section and continues the attachment operation, when there are multiple best suction rates.

6. A component mounting method for changing a pickup height distant from a reference height by a distance indicated by an offset amount during execution of an attachment operation in a component mounting machine in which pickup of a component is performed by a suction tool that is moved to the pickup height each time the attachment operation is performed for attaching the component to a board, the component mounting method comprising:
an attempting step of performing the attachment operation a predetermined count number,
a calculating step of calculating a suction rate indicating a ratio of successfully picking up the component by the suction tool during the attachment operation of the predetermined count number, and
an updating step of updating the offset amount within a predetermined range by adding or subtracting a predetermined distance to or from the offset amount when the suction rate is less than a determination value, and repeating the attempting step and the calculating step.
